(19) United States
(12) Patent Application Publication
(10) Pub. No.: US 2011/0020544 A1
(43) Pub. Date: Jan. 27, 2011

(54) EXHAUST SYSTEM STRUCTURE OF FILM FORMATION APPARATUS, FILM FORMATION APPARATUS, AND EXHAUST GAS PROCESSING METHOD

(75) Inventor: Kenji Matsumoto, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/677,417

(22) PCT Filed: Sep. 1, 2008
(86) PCT No.: PCT/JP08/65661

§ 371 Date: Mar. 10, 2010

(30) Foreign Application Priority Data
Sep. 10, 2007 (JP) 2007-233533

(51) Int. Cl. C23C 16/00

(52) U.S. Cl. 427/248.1; 118/715; 118/723 R

(57) ABSTRACT

An exhaust system structure of a film formation apparatus includes an exhaust line (51) configured to discharge exhaust gas from inside a process container (11); an automatic pressure controller (52) disposed on the exhaust line (51) near the process container (11); a vacuum pump (54) disposed on the exhaust line (51) downstream from the automatic pressure controller (52); an oxidizing agent supply section (57) configured to supply an oxidizing agent into the exhaust line (51) at a position downstream from the automatic pressure controller (52); a trap mechanism (53) disposed on the exhaust line (51) downstream from the position at which the oxidizing agent is supplied and configured to collect a product generated by a reaction of the oxidizing agent with an organic metal source gas component and a by-product contained in the exhaust gas; and a detoxification unit (55) disposed on the exhaust line (51) downstream from the trap mechanism (53).

### TECHNICAL FIELD

The present invention relates to an exhaust system structure of a film formation apparatus for forming a predetermined film by CVD using an organic metal material, and also relates to a film formation apparatus equipped with such an exhaust system structure and an exhaust gas processing method.

### BACKGROUND ART

In the process of manufacturing semiconductor devices, target substrates, such as semiconductor wafers, are subjected to various processes, such as film formation processes, reformation processes, oxidation/diffusion processes, and etching processes.

As a film formation process of this kind widely used, there is a CVD (Chemical Vapor Deposition) method arranged to supply a predetermined process gas into a chamber with a semiconductor wafer placed therein and cause a chemical reaction to form a predetermined film. According to the CVD method, a reaction of a process gas is effected to form a film on a target substrate, such as a semiconductor wafer. However, at this time, the process gas does not necessarily entirely contribute to the reaction, but brings about source gas parts that have not contributed to the film formation as well as reaction by-products. Particularly, CVD apparatuses using organic metal materials generate a large quantity of such source gas parts that have not contributed to the film formation and such reaction by-products.

Source gas parts and by-products of this kind often have some dangers, such as toxicity and ignitability, and thus cannot be released into the atmospheric as they are. In light of this, there is a technique using a trap mechanism to trap and collect most of source gas parts and by-products of this kind, and a detoxification unit to detoxify gas components that have been not collected by the trap mechanism before their atmospheric release (for example, Jpn. Pat. Appln. KOKAI Publication No. 10-140357). The trap mechanism is disposed in a vacuum exhaust system, and includes a cooling fin formed therein to increase the contact area with the exhaust gas (source gas parts and by-products) and to lower the temperature of the exhaust gas to condense it for collection.

However, collected substances condensed and collected inside the trap mechanism are merely physically adsorbed and are still chemically active. Consequently, there is a problem that handling of the trap mechanism may be dangerous. For example, when the trap mechanism is retuned to atmospheric pressure and is detached from the vacuum exhaust system, if atmospheric air comes into the trap mechanism, exhaust gas components adsorbed and collected therein react vigorously with oxygen components and bring about an extremely dangerous situation.

Particularly, where an organic metal material is used, collected substances inside the trap mechanism are highly active in many cases. For example, in the technical field concerning semiconductor devices, MnSiₓO_{y} self-generation barrier films are considered to be promising as diffusion preventing barrier films for Cu interconnections. Where a CuMn film is formed as a seed layer for such a barrier film, an organic Mn compound material is used. However, organic Mn compounds can cause a very vigorous reaction with oxygen components.

Accordingly, where an organic metal material is used, collected substances inside the trap mechanism have to be treated in a very careful manner. For example, a method is adapted to gradually deactivate the collected substances by, e.g., solving the collected substances by use of an organic solvent. However, this method takes a lot of labor hour and further entails a problem concerning the toxicity and/or inflammability of the organic solvent thus used.

### DISCLOSURE OF INVENTION

An object of the present invention is to provide an exhaust system structure of a film formation apparatus, which makes it possible to safely and swiftly treat collected substances inside a trap mechanism, and further to provide a film formation apparatus equipped with such an exhaust system structure and an exhaust gas processing method.

According to a first aspect of the present invention, there is provided an exhaust system structure of a film formation apparatus for forming a film by CVD on a substrate placed inside a process container while supplying a gas containing an organic metal source gas into the process container, the exhaust system structure comprising: an exhaust line configured to discharge exhaust gas from inside the process container; an automatic pressure controller disposed on the exhaust line near the process container; a vacuum pump disposed on the exhaust line downstream from the automatic pressure controller and configured to exhaust gas from inside the process container; an oxidizing agent supply section configured to supply an oxidizing agent, for oxidizing an organic metal source gas component and a by-product contained in the exhaust gas, into the exhaust line at a position downstream from the automatic pressure controller; a trap mechanism disposed on the exhaust line downstream from the position at which the oxidizing agent is supplied and configured to collect a product generated by a reaction of the oxidizing agent with the organic metal source gas component and the by-product contained in the exhaust gas; and a detoxification unit disposed on the exhaust line downstream from the trap mechanism and configured to detoxify the exhaust gas.

In the first aspect, the vacuum pump may be disposed on the exhaust line downstream from the trap mechanism and upstream from the detoxification unit. Alternatively, the vacuum pump may be disposed on the exhaust line downstream from the position at which the oxidizing agent is supplied and upstream from the trap mechanism. Alternatively, the vacuum pump may be disposed on the exhaust line upstream from the position at which the oxidizing agent is supplied.

In the first aspect, the oxidizing agent supply section is preferably configured to supply water as the oxidizing agent. The organic metal material may contain an organic Mn compound material and, in this case, the film contains Mn.

According to a second aspect of the present invention, there is provided a film formation apparatus for forming a film on a substrate, the film formation apparatus comprising: a process container configured to place the substrate therein; a source gas supply mechanism configured to supply a gas containing an organic metal source gas into the process container with the substrate placed therein; a mechanism configured to apply energy to the organic metal source gas to effect a film formation reaction on the substrate; and an exhaust system structure configured to discharge exhaust gas from inside the process container, and to process the exhaust gas, wherein the exhaust system structure includes, an exhaust line configured to discharge exhaust gas from inside the process container, an automatic pressure controller disposed on the exhaust line near the process container, a vacuum pump disposed on the exhaust line downstream from the automatic pressure controller and configured to exhaust gas from inside the process container, an oxidizing agent supply section configured to supply an oxidizing agent, for oxidizing an organic metal source gas component and a by-product contained in the exhaust gas, into the exhaust line at a position downstream from the automatic pressure controller, a trap mechanism disposed on the exhaust line downstream from the position at which the oxidizing agent is supplied and configured to collect a product generated by a reaction of the oxidizing agent with the organic metal source gas component and the by-product contained in the exhaust gas, and a detoxification unit disposed on the exhaust line downstream from the trap mechanism and configured to detoxify the exhaust gas.

In the second aspect, the vacuum pump may be disposed on the exhaust line downstream from the trap mechanism and upstream from the detoxification unit. Alternatively, the vacuum pump may be disposed on the exhaust line downstream from the position at which the oxidizing agent is supplied and upstream from the trap mechanism. Alternatively, the vacuum pump may be disposed on the exhaust line upstream from the position at which the oxidizing agent is supplied.

According to a third aspect of the present invention, there is provided an exhaust gas processing method for a film formation apparatus for forming a film by CVD on a substrate placed inside a process container while supplying a gas containing an organic metal source gas into the process container, the exhaust gas processing method comprising: exhausting gas from inside the process container by a vacuum pump through an exhaust line connected to the process container; supplying an oxidizing agent into exhaust gas during a film formation process downstream from an automatic pressure controller disposed on the exhaust line, thereby oxidizing an organic metal source gas component and a by-product contained in the exhaust gas; collecting by a trap mechanism a product generated by a reaction of the oxidizing agent with the organic metal source gas component and the by-product contained in the exhaust gas; and processing the exhaust gas by a detoxification unit after the product is collected.

In the third aspect, the oxidizing agent is preferably water. The organic metal material may contain an organic Mn compound material and, in this case, the film contains Mn.

According to a fourth aspect of the present invention, there is provided a storage medium that stores a program for execution on a computer to control a film formation apparatus wherein, when executed, the program causes the computer to control an exhaust system of the film formation apparatus to conduct an exhaust gas processing method for the film formation apparatus for forming a film by CVD on a substrate placed inside a process container while supplying a gas containing an organic metal source gas into the process container, the exhaust gas processing method comprising: exhausting gas from inside the process container by a vacuum pump through an exhaust line connected to the process container; supplying an oxidizing agent into exhaust gas during a film formation process downstream from an automatic pressure controller disposed on the exhaust line, thereby oxidizing an organic metal source gas component and a by-product contained in the exhaust gas; collecting by a trap mechanism a product generated by a reaction of the oxidizing agent with the organic metal source gas component and the by-product contained in the exhaust gas; and processing the exhaust gas by a detoxification unit after the product is collected.

According to the present invention, an oxidizing agent supply section is disposed to supply an oxidizing agent, for oxidizing an organic metal source gas component and a by-product contained in the exhaust gas, into the exhaust line of the film formation apparatus at a position downstream from the automatic pressure controller. Further, a trap mechanism is disposed on the exhaust line downstream therefrom to collect a product generated by a reaction of the oxidizing agent with the organic metal source gas component and the by-product contained in the exhaust gas. In this case, the oxidation reaction of the organic metal source gas component and the by-product contained in the exhaust gas is gently caused in the piping line, and the oxide in a deactivated state is collected as the product by the trap mechanism. Consequently, when the trap mechanism is retuned to atmospheric pressure to treat the collected substances, no vigorous reaction is caused, thereby safely and swiftly treating the collected substances inside the trap mechanism. Further, since the collected substances inside the trap mechanism are in a deactivated state, the workload on the detoxification unit is eased so that the service life thereof is prolonged and the labor hour and cost for maintenance thereon are decreased. Particularly, the present invention may be very effectively applied to a case where an organic Mn compound material is used as the organic metal material, because this material is extremely reactive with oxidizing agents.

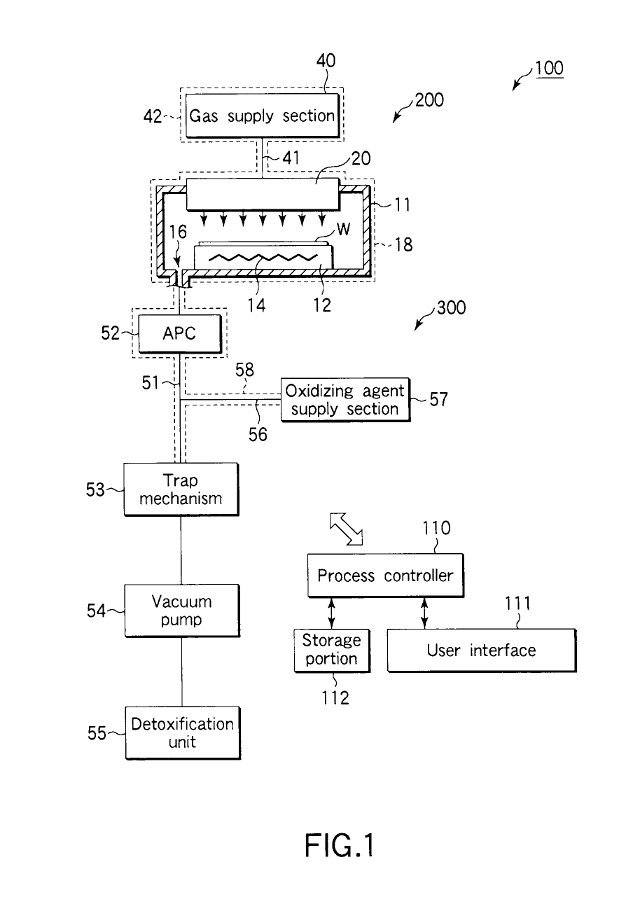

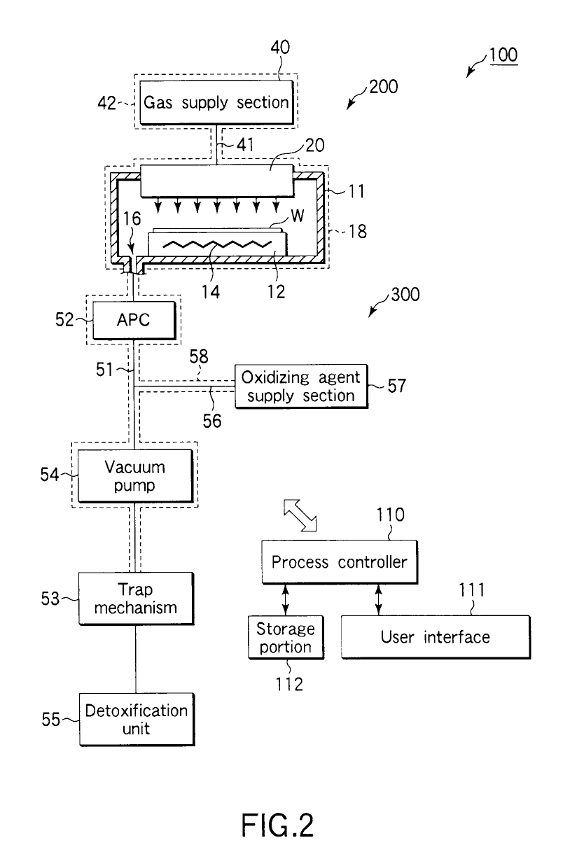

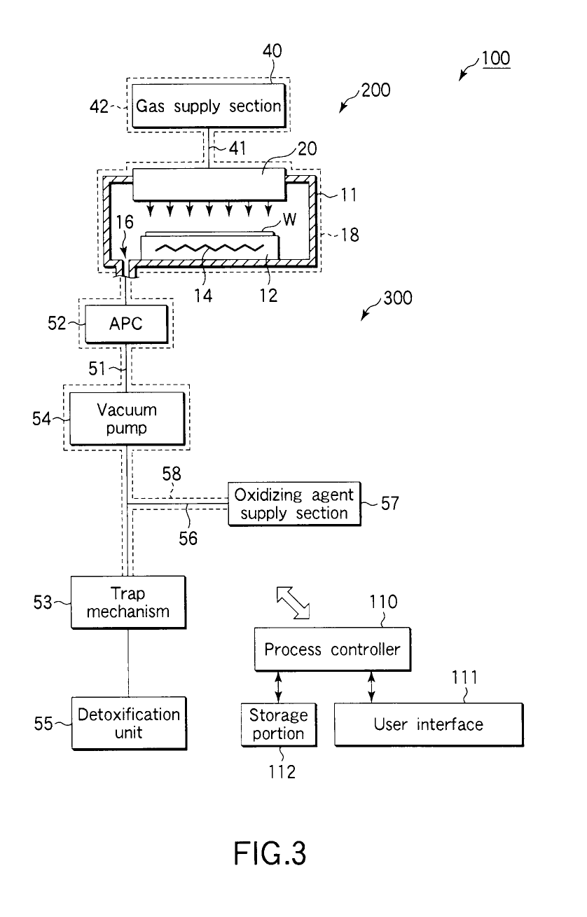

### BRIEF DESCRIPTION OF DRAWINGS

[FIG. 1] This is a schematic view showing a film formation apparatus equipped with an exhaust system structure according to a first embodiment of the present invention.

[FIG. 2] This is a schematic view showing a film formation apparatus equipped with an exhaust system structure according to a second embodiment of the present invention.

[FIG. 3] This is a schematic view showing a film formation apparatus equipped with an exhaust system structure according to a third embodiment of the present invention.

### BEST MODE FOR CARRYING OUT THE INVENTION

Embodiments of the present invention will now be described with reference to the accompanying drawings.

Hereinafter, these embodiments will be exemplified by a case where a semiconductor wafer (which will be simply referred to as a wafer) is used as a target substrate, and a CuMn film is formed on the surface of the wafer by CVD. The CuMn film is to be used as a seed layer for an MnSiₓO_{y} self-generation barrier film serving as a diffusion preventing barrier film for a Cu interconnection.

At first, an explanation will be given of a first embodiment.

FIG. 1 is a schematic view showing a film formation apparatus equipped with an exhaust system structure according to a first embodiment of the present invention. This film formation apparatus 100 generally comprises a film formation processing section 200 and an exhaust system 300.

The film formation processing section 200 includes an essentially cylindrical process chamber 11. The process chamber 11 is provided with a worktable 12 disposed therein at the bottom to place a target substrate or wafer W thereon in a horizontal state. The worktable 12 includes a heater 14 embedded therein and configured to heat the target substrate or wafer W to a predetermined temperature. An exhaust port 16 is formed in the bottom wall of the process chamber 11. Further, a wafer transfer port (not shown) is formed in the side wall of the process chamber 11 and is equipped with a gate valve configured to open and close the transfer port.

The process chamber 11 is further provided with a showerhead 20 serving as a gas feed member disposed therein at the top. The showerhead 20 has a circular disc shape and includes a number of gas delivery holes formed at the bottom.

The showerhead 20 is connected through a piping line 41 to a gas supply section 40 for supplying a source gas, a reducing gas, and so forth for film formation.

The gas supply section 40 is designed to supply the showerhead 20 with an organic Cu compound gas and an organic Mn compound gas as organic metal source gases and H₂ gas as a reducing gas. In this respect, the organic Cu compound serving as a Cu material and the organic Mn compound serving as an Mn material are in a liquid state or sold state. Where either of them is in a sold state, it is dissolved in a solvent for use. Where either of them is in a liquid state, it may be used as it is, but is preferably dissolved in a solvent for use to decrease the viscosity and thereby to improve the vaporization property and handling property. Such materials in a liquid state are vaporized by a suitable mechanism, such as a vaporizer, and are supplied into the showerhead 20. Although FIG. 1 shows one piping line connected to the showerhead 20, for the sake of convenience, the source gases and the reducing gas are supplied to the showerhead 20 through respective piping lines in reality. The showerhead 20 is of the so-called post mix type, in which the source gases and the reducing gas are delivered through different passages and are mixed after they are delivered.

On the other hand, the exhaust system 300 includes an exhaust line 51 connected to the exhaust port 16. The exhaust line 51 is equipped with an automatic pressure controller (APC) 52, a trap mechanism 53, a vacuum pump 54, and a detoxification unit 55 disposed thereon in this order from the upstream side. Further, a portion between the automatic pressure controller (APC) 52 and trap mechanism 53 is connected to a piping line 56, which is connected at the other end to an oxidizing agent supply section 57.

The vacuum pump 54 is used to vacuum-exhaust gas from inside the process chamber 11 through the exhaust line 51, while the pressure inside the process chamber 11 is controlled by the automatic pressure controller (APC) 52. The automatic pressure controller (APC) 52 is configured to control the exhaust rate through the exhaust line 51 by adjusting the opening degree of a valve to set the pressure inside the process chamber 11 at a predetermined value, while monitoring the pressure inside the process chamber 11 by a pressure gauge (not shown).

For example, the oxidizing agent supply section 57 is designed to supply H₂O as an oxidizing agent so as to supply H₂O through the piping line 56 into the exhaust gas flowing through the exhaust line 51. The exhaust gas contains unreacted components of the organic metal source gases and by-products, which react with H₂O serving as an oxidizing agent and thereby generate oxide-containing products. The H₂O supply system employed here may be of a well-known gas supply type, such as the bubbling type, heating-evaporation type, liquid vaporization type, liquid atomization type, or ultrasonic type.

The trap mechanism 53 is configured to trap oxide-containing products generated by supplying the oxidizing agent into the exhaust gas. In general, products of this kind are powder, and so a powder collection trap is used as the trap mechanism 53. The powder collection trap employed here may be formed of a conventionally well-known trap mechanism, such as a cooling trap, baffle trap, filter trap, cyclone trap, electrostatic trap, gravity trap, or inertia trap.

The vacuum pump 54 may be formed of a dry pump. Where a higher level vacuum is required, a turbo-molecular pump (TMP) may be disposed downstream from the automatic pressure controller (APC) 52 and upstream from the meeting point of the oxidizing agent supply piping line 56, in addition to the dry pump.

The detoxification unit 55 is configured to detoxify toxic components remaining in the exhaust gas after the products in the exhaust gas are trapped by the trap mechanism 53. The detoxification unit employed here may be of a conventionally well-known type, such as the heating catalyst type, combustion type, adsorption type, or plasma reaction type.

A heater 42 is provided to heat the piping line of the gas supply section 40 and so forth. A heater 18 is provided to heat the process chamber 11 and showerhead 20. A heater 58 is provided to heat a portion of the exhaust line 51 down to a position immediately before the trap mechanism 53, the automatic pressure controller (APC) 52, and the piping line 56. The heating of these portions can prevent the organic metal source gases from being condensed in the area down to the trap mechanism 53.

The respective components of the film formation apparatus 100 are connected to and controlled by a process controller 110 comprising a microprocessor (computer). The process controller 110 is connected to a user interface 111, which includes, e.g., a keyboard and a display, wherein the keyboard is used for an operator to input commands for operating the film formation apparatus 100, and the display is used for showing visualized images of the operational status of the film formation apparatus 100. The process controller 110 is further connected to a storage portion 112, which stores recipes i.e., control programs for the process controller 110 to control the film formation apparatus 100 so as to perform various processes, and programs for the respective components of the film formation apparatus 100 to perform processes in accordance with process conditions. The recipes are stored in the storage medium of the storage portion 112. The storage medium may be of the stationary type, such as a hard disk, or of the portable type, such as a CDROM, DVD, or flash memory. Alternatively, the recipes may be used while they are transmitted from another apparatus through, e.g., a dedicated line.

As needed, a required recipe is retrieved from the storage portion 112 and executed by the process controller 110 in accordance with an instruction or the like input through the user interface 111. Consequently, the film formation apparatus 100 can perform a predetermined process under the control of the process controller 110.

Particularly, in this embodiment, the process controller 110 controls the exhaust system 300 of the film formation apparatus 100 to perform exhaust operations in accordance with exhaust operation recipes stored in the storage portion 112.

Next, an explanation will be given of a process sequence performed in the film formation apparatus 100 described above.

At first, the vacuum pump 54 of the exhaust system 300 is operated to vacuum-exhaust gas from inside the process chamber 11 and the automatic pressure controller (APC) 52 is operated to set the process chamber 11 at a predetermined pressure. While these operations are kept performed, a wafer W is loaded into the chamber 11 with a vacuum atmosphere maintained therein and is placed on the susceptor 12.

In this state, the organic metal materials, i.e., the organic Cu compound gas and organic Mn compound gas, and the reducing gas, i.e., H₂ gas, are supplied at predetermined flow rates from the gas supply section 40 through the showerhead 20 into the process chamber 11. At the same time, the wafer W is heated by the heater 14 to a temperature of, e.g., 100 to 450° C. Consequently, the organic Cu compound gas and organic Mn compound gas react with the reducing gas, i.e., H₂ gas, on the wafer W and a CuMn film is thereby formed on the wafer W.

During this film formation process, the exhaust gas is discharged from the process chamber 11 through the exhaust line 51. Since the organic metal source gases are used, the organic metal source gases do not entirely contribute to the reaction, but bring about a lot of organic metal source gas parts that have not contributed to the film formation as well as reaction by-products. These organic metal source gas parts and reaction by-products are active. Particularly, the organic Mn compound gas used in this embodiment is highly active and can react vigorously with an oxidizing agent, such as H₂O, and so it is designated as a “water-reactive” substance in general.

Specifically, the organic metal source gases, particularly the organic Mn compound gas, are still highly active when they are merely physically adsorbed on the trap mechanism, as in the conventional technique. In this state, if the trap mechanism is set open to atmospheric air, they may cause a vigorous reaction and bring about an extremely dangerous situation. Accordingly, handling of the trap mechanism takes a lot of labor hour to circumvent such dangers.

According to this embodiment made in light of this problem, H₂O serving as an oxidizing agent is supplied from the oxidizing agent supply section 57 through the piping line 56 into the exhaust line 51 at a position downstream from the automatic pressure controller (APC) 52. The H₂O thus supplied gently causes an oxidation reaction in the exhaust line 51, which corresponds to a reaction caused by exposure to atmospheric air as described above, and generates oxide-containing products in the exhaust line 51. The oxide-containing products are then trapped and collected by the trap mechanism 53. At this time, since the H₂O serving as an oxidizing agent is supplied downstream from the automatic pressure controller (APC) 52, it does not affect the film formation process.

The oxide-containing products thus generated are in a deactivated state and do not cause a vigorous reaction if the trap mechanism 53 is set open to atmospheric air, and so the collected substances inside the trap mechanism 53 can be treated safely and swiftly. Further, since the collected substances inside the trap mechanism 53 are in a deactivated state, the workload on the detoxification unit 55 is eased so that the service life thereof is prolonged and the labor hour and cost for maintenance thereon are decreased.

The deactivation process by use of H₂O serving as an oxidizing agent is particularly effective on the organic Mn compound, which can react vigorously with H₂O. As a matter of course, the organic Cu compound also reacts with H₂O and receives benefit to some extent from this reaction, although it is smaller than that of the organic Mn compound.

In this embodiment, the organic Mn compound is preferably exemplified by (EtCp)₂Mn, (MeCp)₂Mn, (i-PrCp)₂Mn, Cp2Mn, and (MeCp)Mn(CO)₃. Further, in this embodiment, the organic Cu compound is exemplified by Cu(hfac)TMVS and the like.

For example, where the organic Mn compound is (EtCp)₂Mn, the reaction of the organic Mn compound and H₂O is expressed as shown in the following formula (1). As shown in this formula, Mn in the compound is oxidized and turned into MnO or MnO₂, and EtCp serving as the organic skeleton portion is combined with H and turned into EtCpH or (EtCpH)₂. In this state, they flow downstream and detoxified in the detoxification unit 55.

(EtCp)₂Mn+H₂O→2EtCpH+MnO (1)

Next, an explanation will be given of a second embodiment.

FIG. 2 is a schematic view showing a film formation apparatus equipped with an exhaust system structure according to a second embodiment of the present invention. In this second embodiment, the vacuum pump 54 is disposed between a supply position of H₂O serving as an oxidizing agent and the trap mechanism 53, i.e., at a position different from that of the first embodiment. In this case, after the H₂O is supplied from the oxidizing agent supply section 57 through the piping line 56 into the exhaust line 51, the exhaust gas flows through the vacuum pump 54 into the trap mechanism 53. Consequently, the exhaust gas is sufficiently mixed with the H₂O serving as an oxidizing agent in the vacuum pump 54 and thereby completely reacts with the H₂O, before it is collected in the trap mechanism 53. In this respect, according to the first embodiment described above, the pressure at the H₂O supply position on the exhaust line 51 is lower, and the exhaust gas is trapped in the trap mechanism 53 immediately after it is mixed with H₂O in the exhaust line 51, whereby the reaction of exhaust gas components with H₂O may have a difficulty in progress. Accordingly, the second embodiment is preferable in light of reactivity.

However, in the second embodiment, since the exhaust gas flows through the vacuum pump 54 before it reaches the trap mechanism 53, the vacuum pump 54 needs to be heated to prevent source gas parts in the exhaust gas from being condensed, and thus requires the heater 58 to be further disposed on the vacuum pump 54, as shown in FIG. 2. Further, since the exhaust gas is mixed with H₂O in the vacuum pump 54 and generates oxide-containing products, the workload of the vacuum pump 54 is increased. In these respects, according to the first embodiment, the vacuum pump 54 bears a smaller workload and requires no heating.

Next, an explanation will be given of a third embodiment.

FIG. 3 is a schematic view showing a film formation apparatus equipped with an exhaust system structure according to a third embodiment of the present invention. In this third embodiment, the vacuum pump 54 is disposed between the automatic pressure controller (APC) 52 and a supply position of H₂O serving as an oxidizing agent, i.e., at a position different from those of the first and second embodiments. In this case, after the exhaust gas flows through the vacuum pump 54, the H₂O is supplied to the exhaust gas, whereby the reaction of the exhaust gas and H₂O is caused at a higher pressure, and thus the reaction proceeds easily. Further, since the H₂O does not flow through the vacuum pump 54, the vacuum pump 54 is prevented from suffering oxide-containing products generated therein and the workload of the vacuum pump 54 is decreased. However, as in the second embodiment, since the exhaust gas flows through the vacuum pump 54 before it reaches the trap mechanism 53, the vacuum pump 54 needs to be heated to prevent source gas parts in the exhaust gas from being condensed, and thus requires the heater 58 to be further disposed on the vacuum pump 54, as shown in FIG. 3.

The first to third embodiments described above have their own good and bad points, and thus it is preferable to selectively use them in accordance with the situation.

The present invention is not limited to the embodiments described above, and it may be modified in various manners. For example, in the embodiments described above, the oxidizing agent is exemplified by H₂O, but this is not limiting. The oxidizing agent can be anything that contains oxygen as a component, such as O₃, O₂, H₂O₂, NO₂, N₂O, an alcohol, an organic solvent, an organic acid, or air. Further, the oxidizing agent can be a substance containing a halogen, such as Cl₂, other than a substance containing oxygen. However, where H₂ is used as a reducing gas in forming a CuMn film, an oxidizing agent incompatible with H₂ for mixing should not be used.

Further, in the embodiments described above, the organic Mn compound and organic Cu compound, and particularly the organic Mn compound, are explained as examples of an organic metal material, but this is not limiting. The organic metal material can be anything that reacts with an oxidizing agent, and for example, it may be an organic compound of another metal, such as Al, Ti, Fe, Co, Ni, Zn, Zr, Ru, Hf, Ta, or W.

Further, in the embodiments described above, the target substrate is exemplified by a semiconductor wafer, but this is not limiting. The target substrate may be another substrate, such as a glass substrate used for a flat panel display (FPD), which is represented by a liquid crystal display (LCD).

Further, in the embodiments described above, the film formation apparatus is exemplified by a single-substrate type, but this is not limiting. The present invention may be applied to a film formation apparatus of the batch type that processes a number of target substrates all together.

1. An exhaust system structure of a film formation apparatus for forming a film by CVD on a substrate placed inside a process container while supplying a gas containing an organic metal source gas into the process container, the exhaust system structure comprising:
an exhaust line configured to discharge exhaust gas from inside the process container;
an automatic pressure controller disposed on the exhaust line near the process container;
a vacuum pump disposed on the exhaust line downstream from the automatic pressure controller and configured to exhaust gas from inside the process container;
an oxidizing agent supply section configured to supply an oxidizing agent, for oxidizing an organic metal source gas component and a by-product contained in the exhaust gas, into the exhaust line at a position downstream from the automatic pressure controller;
a trap mechanism disposed on the exhaust line downstream from the position at which the oxidizing agent is supplied and configured to collect a product generated by a reaction of the oxidizing agent with the organic metal source gas component and the by-product contained in the exhaust gas; and
a detoxification unit disposed on the exhaust line downstream from the trap mechanism and configured to detoxify the exhaust gas.

2. The exhaust system structure of a film formation apparatus according to claim 1, wherein the vacuum pump is disposed on the exhaust line downstream from the trap mechanism and upstream from the detoxification unit.

3. The exhaust system structure of a film formation apparatus according to claim 1, wherein the vacuum pump is disposed on the exhaust line downstream from the position at which the oxidizing agent is supplied and upstream from the trap mechanism.

4. The exhaust system structure of a film formation apparatus according to claim 1, wherein the vacuum pump is disposed on the exhaust line upstream from the position at which the oxidizing agent is supplied.

5. The exhaust system structure of a film formation apparatus according to claim 1, wherein the oxidizing agent supply section is configured to supply water as the oxidizing agent.

6. The exhaust system structure of a film formation apparatus according to claim 1, wherein the organic metal material contains an organic Mn compound material and the film contains Mn.

7. A film formation apparatus for forming a film on a substrate, the film formation apparatus comprising:
a process container configured to place the substrate therein;
a source gas supply mechanism configured to supply a gas containing an organic metal source gas into the process container with the substrate placed therein;
a mechanism configured to apply energy to the organic metal source gas to effect a film formation reaction on the substrate; and
an exhaust system structure configured to discharge exhaust gas from inside the process container, and to process the exhaust gas,
wherein the exhaust system structure includes,
an exhaust line configured to discharge exhaust gas from inside the process container,
an automatic pressure controller disposed on the exhaust line near the process container,
a vacuum pump disposed on the exhaust line downstream from the automatic pressure controller and configured to exhaust gas from inside the process container,
an oxidizing agent supply section configured to supply an oxidizing agent, for oxidizing an organic metal source gas component and a by-product contained in the exhaust gas, into the exhaust line at a position downstream from the automatic pressure controller,
a trap mechanism disposed on the exhaust line downstream from the position at which the oxidizing agent is supplied and configured to collect a product generated by a reaction of the oxidizing agent with the organic metal source gas component and the by-product contained in the exhaust gas, and
a detoxification unit disposed on the exhaust line downstream from the trap mechanism and configured to detoxify the exhaust gas.

8. The film formation apparatus according to claim 7, wherein the vacuum pump is disposed on the exhaust line downstream from the trap mechanism and upstream from the detoxification unit.

9. The film formation apparatus according to claim 7, wherein the vacuum pump is disposed on the exhaust line downstream from the position at which the oxidizing agent is supplied and upstream from the trap mechanism.

10. The film formation apparatus according to claim 7, wherein the vacuum pump is disposed on the exhaust line upstream from the position at which the oxidizing agent is supplied.

11. An exhaust gas processing method for a film formation apparatus for forming a film by CVD on a substrate placed inside a process container while supplying a gas containing an organic metal source gas into the process container, the exhaust gas processing method comprising:
exhausting gas from inside the process container by a vacuum pump through an exhaust line connected to the process container;
supplying an oxidizing agent into exhaust gas during a film formation process downstream from an automatic pressure controller disposed on the exhaust line, thereby oxidizing an organic metal source gas component and a by-product contained in the exhaust gas;
collecting by a trap mechanism a product generated by a reaction of the oxidizing agent with the organic metal source gas component and the by-product contained in the exhaust gas; and
processing the exhaust gas by a detoxification unit after the product is collected.

12. The exhaust gas processing method according to claim 11, wherein the oxidizing agent is water.

13. The exhaust gas processing method according to claim 11, wherein the organic metal material contains an organic Mn compound material and the film contains Mn.

14. A storage medium that stores a program for execution on a computer to control a film formation apparatus wherein, when executed, the program causes the computer to control an exhaust system of the film formation apparatus to conduct an exhaust gas processing method for the film formation apparatus for forming a film by CVD on a substrate placed inside a process container while supplying a gas containing an organic metal source gas into the process container, the exhaust gas processing method comprising:
exhausting gas from inside the process container by a vacuum pump through an exhaust line connected to the process container;
supplying an oxidizing agent into exhaust gas during a film formation process downstream from an automatic pressure controller disposed on the exhaust line, thereby oxidizing an organic metal source gas component and a by-product contained in the exhaust gas;
collecting by a trap mechanism a product generated by a reaction of the oxidizing agent with the organic metal source gas component and the by-product contained in the exhaust gas; and
processing the exhaust gas by a detoxification unit after the product is collected.
